(19) United States
(12) Patent Application Publication
(10) Pub. No.: US 2022/0066301 A1
(43) Pub. Date: Mar. 3, 2022

(54) WAVELENGTH CONVERSION ELEMENT, LIGHT SOURCE APPARATUS, AND IMAGE PROJECTION APPARATUS

(71) Applicant: CANON KABUSHIKI KAISHA, Tokyo (JP)

(72) Inventors: Hiroshi Yamamoto, Tokyo (JP); Yuya Kurata, Tokyo (JP); Shigefumi Watanabe, Tokyo (JP)

(21) Appl. No.: 17/407,588

(22) Filed: Aug. 20, 2021

(30) Foreign Application Priority Data
Sep. 1, 2020 (JP) 2020-146627

(51) Int. Cl. G03B 21/20; H01L 33/50; H01L 25/075

(52) U.S. Cl. CPC G03B 21/204; H01L 2933/0091; H01L 25/0753; H01L 33/504

(57) ABSTRACT

A wavelength conversion element made of a sintered body includes a fluorescent member, a light-transmitting member having a thermal conductivity higher than that of the fluorescent member, and a light-scattering member having a refractive index higher than that of the light-transmitting member, and an average particle radius of 75 nm or more and 200 nm or less.

### BACKGROUND OF THE INVENTION

### Field of the Invention

The present invention relates to a wavelength conversion element, a light source apparatus, and an image projection apparatus.

### Description of the Related Art

One conventional image projection apparatus (projector) irradiates excitation light from a light source to a wavelength conversion element, such as a phosphor, guides illumination light generated by using converted light emitted from the wavelength conversion element to a light modulation element, such as a liquid crystal element and a digital micromirror device, and projects an image.

Japanese Patent Laid-Open No. (“JP”) 2018-53227 discloses a projector using a sintered phosphor (fluorescent material or body) that includes Y₃Al₅O₁₂:Ce (YAG:Ce) and a ceramic material having a refractive index different from that of YAG:Ce. The sintered phosphor has a good light-scattering characteristic since the internal crystal grain boundary has voids (or pores), and can improve the light utilization efficiency of the projector. JP 2019-28306 discloses a sintered phosphor made of a mixture of Al₂O₃ and YAG:Ce, which are excellent in heat conduction, in order to improve the heat radiation of the phosphor.

However, it is difficult for the configurations disclosed in JPs 2018-53227 and 2019-28306 to stably improve the heat radiation characteristic and the light utilization efficiency of the sintered phosphor. Since the shape and volume ratio of the voids of the crystal grain boundary inside the sintered phosphor greatly depend on the sintering process and the temperature distribution in the sintering furnace, it is difficult to stabilize the shape and volume ratio of the voids. If the shape and volume ratio of the voids are not stable, the heat radiation and light utilization efficiency of the sintered phosphor will not become stable.

### SUMMARY OF THE INVENTION

The present invention provides a wavelength conversion element, a light source apparatus, and an image projection apparatus, each of which can stably improve heat radiation and light utilization efficiency.

A wavelength conversion element according to one aspect of the present invention is made of a sintered body and includes a fluorescent member, a light-transmitting member having a thermal conductivity higher than that of the fluorescent member, and a light-scattering member having a refractive index higher than that of the light-transmitting member, and an average particle radius of 75 nm or more and 200 nm or less. A light source apparatus and an image projection apparatus having the above wavelength conversion element also constitute another aspect of the present invention.

Further features of the present invention will become apparent from the following description of exemplary embodiments with reference to the attached drawings.

### BRIEF DESCRIPTION OF THE DRAWINGS

FIG. 1 is a sectional view of a phosphor (fluorescent material or body) according to a first embodiment.

FIG. 2 is an explanatory diagram of a blur amount of fluorescent light according to the first embodiment.

FIG. 3 is a configuration diagram of an image projection apparatus according to a second embodiment.

FIG. 4 is an explanatory diagram of a spectrum of light emitted from a light source apparatus according to the second embodiment.

FIG. 5 illustrates a relationship between B/Y and the blur amount in the second embodiment.

FIG. 6 illustrates a relationship between a refractive index of light-scattering particles and B/Y in the second embodiment.

FIG. 7 illustrates a relationship between an average particle radius of the light-scattering particles and B/Y in the second embodiment.

FIG. 8 illustrates a relationship between a volume ratio of the light-scattering particles and B/Y in the second embodiment.

FIG. 9 illustrates a relationship between a refractive index and a blur amount of the light-scattering particles in the second embodiment.

FIG. 10 illustrates a relationship between an average particle radius of the light-scattering particles and a blur amount in the second embodiment.

FIG. 11 illustrates a relationship between a volume ratio of the light-scattering particles and the blur amount in the second embodiment.

FIG. 12 is a configuration diagram of an image projection apparatus according to a third embodiment.

### DESCRIPTION OF THE EMBODIMENTS

Referring now to the accompanying drawings, a detailed description will be given of embodiments according to the present invention.

### First Embodiment

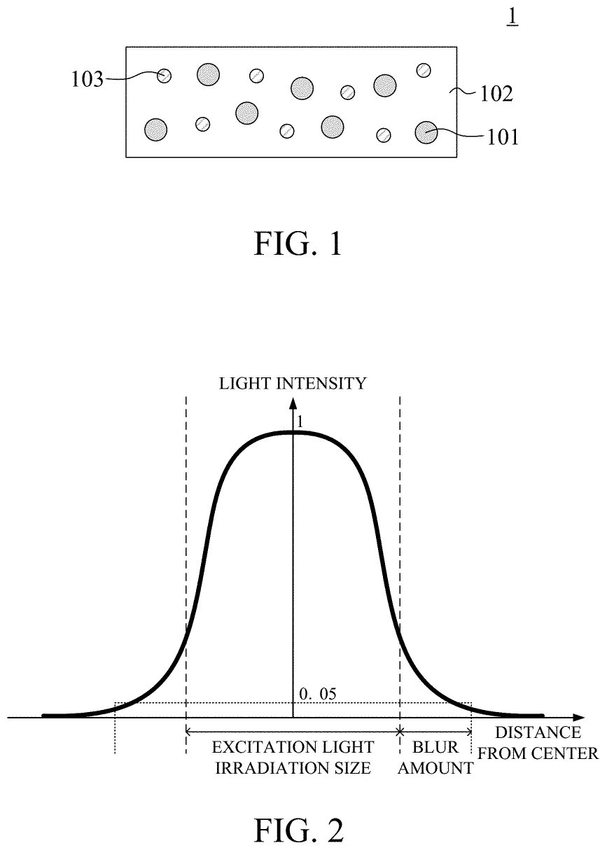

Referring now to FIG. 1, a description will be given of a configuration of a phosphor (wavelength conversion element) 1 according to a first embodiment of the present invention. FIG. 1 is a sectional view of the phosphor 1 according to this embodiment. The phosphor 1 is made of a sintered ceramic material. Reference numeral 101 denotes a fluorescent member (fluorescent phase), reference numeral 102 denotes a light-transmitting member (light-transmitting phase), and reference numeral 103 denotes a light-scattering member (light-scattering particles).

In this embodiment, the fluorescent member 101 is made of YAG:Ce (Y₃Al₅O₁₂:Ce), the light-transmitting member 102 is made of Al₂O₃, and the light-scattering member 103 is made of TiO₂. YAG:Ce is a yellow phosphor that emits yellow fluorescent light when receiving excitation light. The phosphor 1 may have a thickness of 50 μm or more and 400 μm or less, and the phosphor 1 according to this embodiment has a thickness of 200 μm. Each of the fluorescent member 101 and the light-scattering member 103 may have a granular shape. This structure facilitates manufacturing of the phosphor 1. In this embodiment, YAG:Ce has an average crystal particle radius of 0.5 μm and TiO₂ has an average crystal particle radius of 0.4 μm. However, the average particle radius of TiO₂ may be 75 nm or more and 200 nm or less.

In the visible wavelength range, YAG:Ce has a refractive index of 1.83, Al₂O₃ has a refractive index of 1.768, and TiO₂ has a refractive index of 2.72. The crystal structure of TiO₂ has an anatase type and a rutile type, but the rutile type has a higher refractive index and therefore has a higher scattering function. TiO₂ in this embodiment has a rutile type crystal structure. Due to a large difference between the refractive index of the light-scattering member 103 made of TiO₂ and that of the light-transmitting member 102 made of Al₂O₃, the light-scattering member 103 may serve as a light-scattering source. Therefore, a blur amount of fluorescent light, which will be described later, can be reduced.

Referring now to FIG. 2, a description will be given of the blur amount of the fluorescent light emitted from the phosphor 1. FIG. 2 is an explanatory diagram (emission profile of the fluorescent light) of the blur amount of the fluorescent light emitted from the phosphor 1. The emission profile in FIG. 2 is one at the center of the light emitting surface of the phosphor 1. In FIG. 2, the ordinate axis represents a light intensity and the abscissa axis represents a distance from a light emitting center. In the emission profile, the blur amount is defined as a distance from the excitation light irradiation area (the end of the excitation light irradiation size) to a position where the light intensity becomes 5% of the maximum value. When the blur amount becomes large, the etendue of the fluorescent light emitted from the phosphor 1 becomes large and reduces the light utilization efficiency when the fluorescent light is taken in by an optical system such as a lens. Therefore, the fluorescent light may have a small blur amount.

Next follows a description of a method for manufacturing the phosphor 1 according to this embodiment. Each powder of YAG:Ce constituting the fluorescent member 101, Al₂O₃ constituting the light-transmitting member 102, and TiO₂ constituting the light-scattering member 103 is weighed, put into a ball mill together with ethanol, pulverized, and mixed. The obtained slurry is dried and granulated, and the obtained granulated powder is press-molded. Then, the obtained molded product is burned in an air atmosphere at a temperature of about 1500° C. or higher and 1800° C. or lower. Since TiO₂ has a melting point of 1850° C., which is higher than the burning temperature, the shape and volume ratio (ratio of the volume of the light-scattering member 103 to that of the phosphor 1) contained in the sintered body can substantially maintain those in the pre-burning state.

Thus, the shape and volume ratio of TiO₂ making the light-scattering member 103 included in the phosphor 1 which is the wavelength conversion element according to this embodiment can be stabler than those in the prior art which uses voids for light-scattering particles. In addition, since TiO₂ has a thermal conductivity of 10.7 W/m·K, which is higher than a thermal conductivity of 0.024 W/m·K of the voids, the thermal conductivity of the phosphor 1 can be improved.

### Second Embodiment

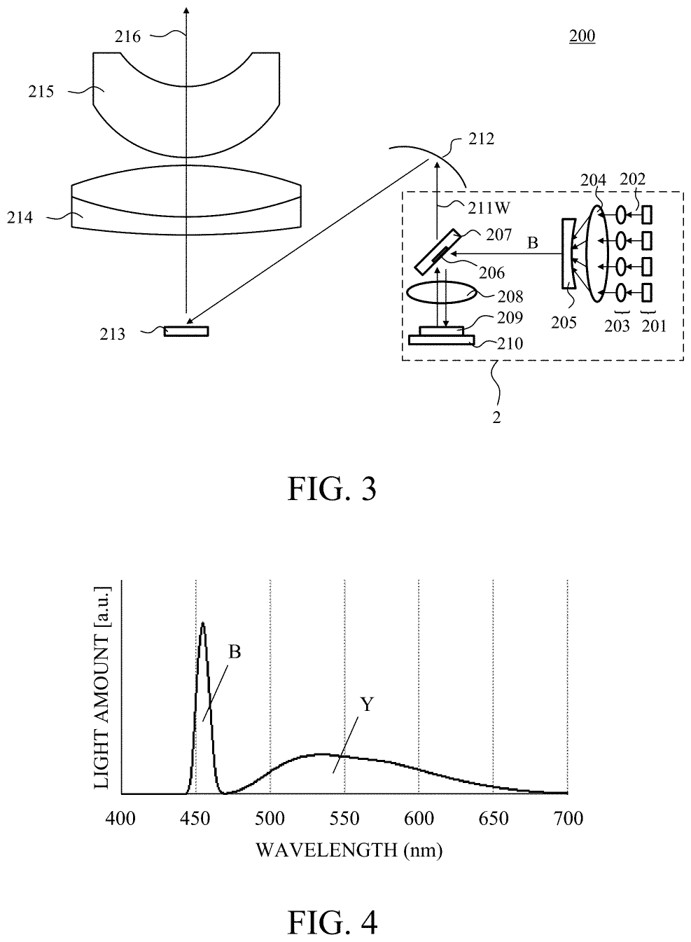

Referring now to FIG. 3, a description will be given of an image projection apparatus (projector) 200 according to a second embodiment of the present invention. FIG. 3 is a configuration diagram of the image projection apparatus 200. The image projection apparatus 200 includes a light source apparatus 2.

Reference numeral 201 denotes each of a plurality of first blue light sources, reference numeral 202 denotes first blue light, reference numeral 203 denotes each of a plurality of first collimator lenses, reference numeral 204 denotes a first lens, and reference numeral 205 denotes a second lens. Reference numeral 206 denotes a first dichroic film, reference numeral 207 denotes a first flat plate, reference numeral 208 denotes a third lens, reference numeral 209 denotes a first phosphor (fluorescent material or body, wavelength conversion element), reference numeral 210 denotes a first phosphor support member, and reference numeral 211W denotes illumination light. Reference numeral 212 denotes a first mirror, reference numeral 213 denotes a first light modulation element, reference numeral 214 denotes a fourth lens, reference numeral 215 is a fifth lens, and reference numeral 216 denotes projection light.

The first blue light source 201 includes a semiconductor laser that emits the first blue light (which may be simply referred to as blue light hereinafter) 202, and serves as an excitation light source that excites the first phosphor 209 as the wavelength conversion element. The first phosphor 209 has the same structure as that of the phosphor 1 illustrated in FIG. 1. The image projection apparatus 200 according to this embodiment has four first blue light sources 201, but the number of first blue light sources 201 is not limited to four. The blue light emitted from the first blue light source 201 has a peak wavelength of 455 nm.

The first blue light 202 as divergent light emitted from the first blue light source 201 is converted into substantially parallel light by the first collimator lens 203 and enters the first lens 204 as a beam shaping lens. The second lens 205 adjusts the sectional shape of the first blue light 202 from the first collimating lens 203. The first blue light 202 as the excitation light emitted from the first lens 204 is reflected on the first dichroic film 206 provided on part of the first flat plate 207, and is irradiated onto the first phosphor 209 via the third lens 208. The first flat plate 207 is made of a glass material. The first dichroic film 206 has a characteristic of transmitting the blue light and reflecting the yellow light.

The first phosphor 209 is a sintered material or sintered body made of YAG:Ce, Al₂O₃, and TiO₂, similar to the phosphor 1 in the first embodiment. The first phosphor 209 has a size of 5 mm in length×5 mm in width×0.2 mm in thickness. The first blue light 202 is irradiated onto the first phosphor 209 substantially uniformly with a length of 1 mm and a width of 1 mm. The first phosphor 209 is supported by the first phosphor support member 210. The first phosphor support member 210 is typically made of a metal plate such as copper. However, it is not limited to the metal plate as long as it has the same function as the metal plate. In order to efficiently radiate heat from the first phosphor 209, the first phosphor 209 and the first phosphor support member 210 may be rotated by a motor or the like. The first phosphor 209 wavelength-converts part of the first blue light 202 into yellow fluorescent light, which is combined with the nonconverted blue excitation light to form white illumination light (illumination light 211W).

The illumination light 211W is reflected on the first mirror 212 and enters the first light modulation element 213. The first light modulation element 213 includes a digital micromirror device, modulates the incident white illumination light (illumination light 211W) based on a video signal (image information) input to the image projection apparatus 200, and forms the image light. White projection light 216, which is modulated by the light modulation element 213 and becomes the image light, is magnified and projected onto a projection surface such as an unillustrated screen via the fourth lens 214 and the fifth lens 215. Thereby, a white projection image is displayed.

Referring now to FIG. 4, a description will be given of the spectrum of the light emitted from the light source apparatus 2. FIG. 4 is an explanatory diagram of the spectrum of light emitted from the light source apparatus 2. In FIG. 4, the ordinate axis represents a light amount (au) and the abscissa axis represents a wavelength (nm). As illustrated in FIG. 4, the light emitted from the light source apparatus 2 is a mixture of the fluorescent light emitted by the first phosphor 209 and the unconverted excitation light. Therefore, in order to obtain suitable white light, of the light emitted from the light source apparatus 2, a ratio (B/Y hereinafter) of a light amount B of the excitation light (light amount in the wavelength range of the first blue light source 201) to a light amount Y of the fluorescent light (light amount in the wavelength range of the wavelength conversion element) may be set to a predetermined range. In this embodiment, the predetermined range of B/Y is 0.28 or more and 0.56 or less in order to obtain the suitable white light.

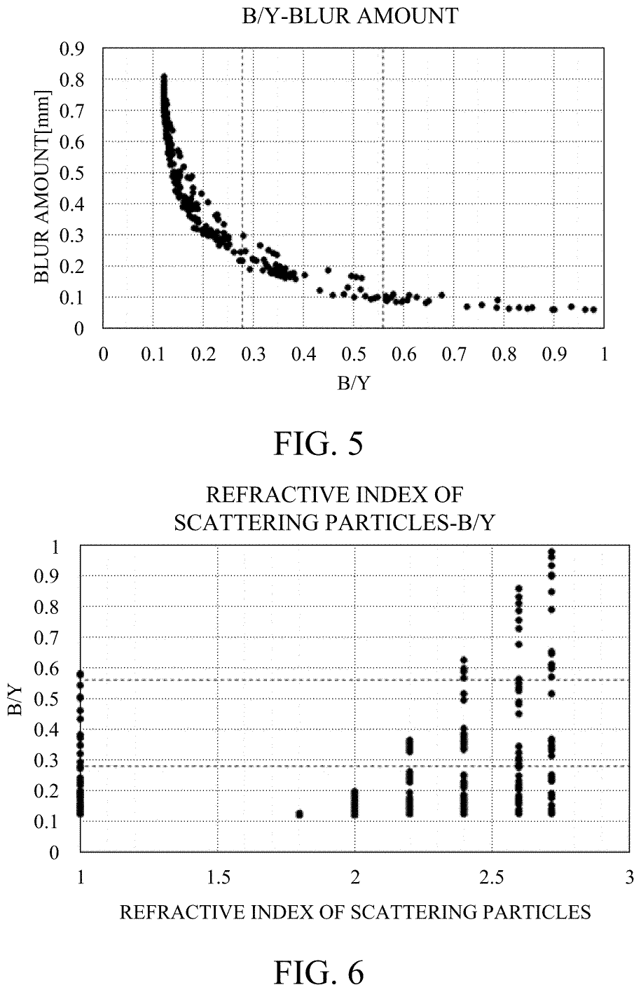

FIG. 5 illustrates a relationship between B/Y and the blur amount against the refractive index, the average particle radius, and the volume ratio of the light-scattering particles contained in the first phosphor 209. In FIG. 5, the ordinate axis represents the blur amount (mm), and the abscissa axis represents B/Y.

Dotted lines in FIG. 5 indicate a lower limit value (=0.28) and an upper limit value (=0.56) of the proper B/Y so as to obtain the above white color. This is similarly applied to FIGS. 6 to 8. The refractive index of the light-scattering particles is calculated in the range of 1 to 2.72, the average particle radius of the light-scattering particles is calculated in the range of 50 to 500 nm, and the volume ratio of the light-scattering particles is calculated in the range of 0.1 to 10%. The condition of the refractive index of 1 is calculated for comparison with the prior art that uses voids for the light-scattering particles. As understood from FIG. 5, in order to obtain a proper B/Y, it is necessary to properly combine parameters, and even if B/Y is the same, the blur amount can be reduced by more properly combining the parameters.

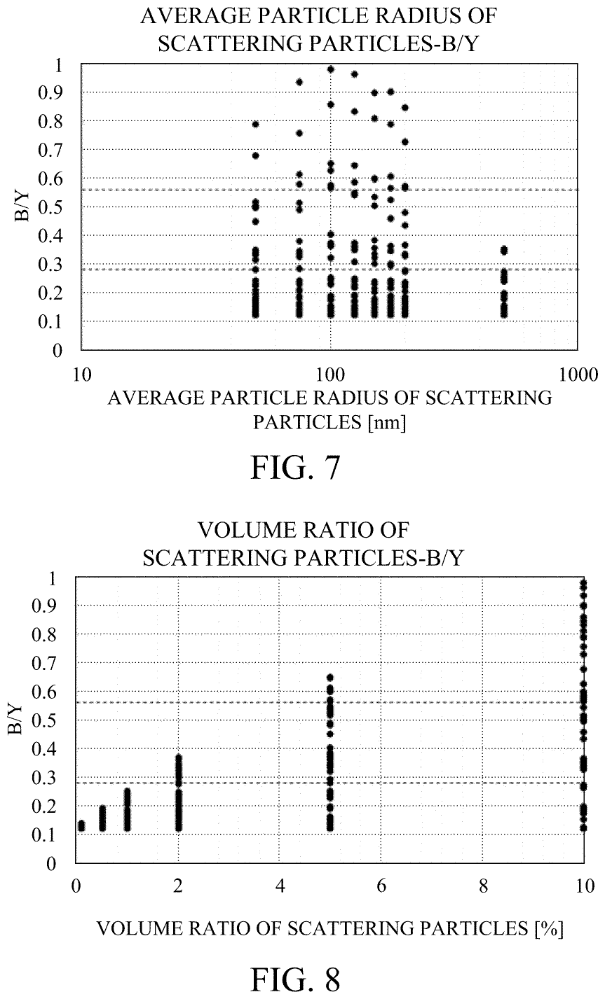

FIG. 6 illustrates a relationship between the refractive index of light-scattering particles and B/Y. In FIG. 6, the ordinate axis represents B/Y and the abscissa axis represents the refractive index of the light-scattering particles. FIG. 7 illustrates a relationship between the average particle radius of the light-scattering particles and B/Y. In FIG. 7, the ordinate axis represents B/Y, and the abscissa axis represents the average particle radius (nm) of the light-scattering particles. FIG. 8 illustrates a relationship between the volume ratio of light-scattering particles (ratio of the volume of light-scattering particles to the volume of the wavelength conversion element) and B/Y. In FIG. 8, the ordinate axis represents B/Y, and the abscissa axis represents the volume ratio (%) of light-scattering particles. In order to obtain proper B/Y, the refractive index of the light-scattering particles may be 2.2 or more, as illustrated in FIG. 6. From FIG. 7, the average particle radius of the light-scattering member may be 75 nm or more and 200 nm or less. From FIG. 8, the volume ratio of the light-scattering particles may be 2% or higher.

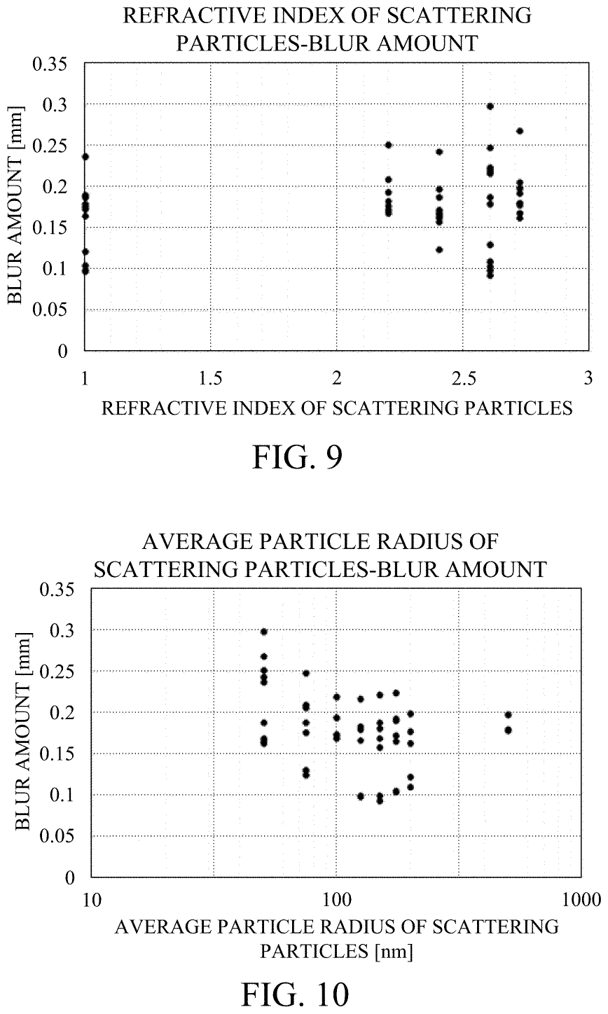

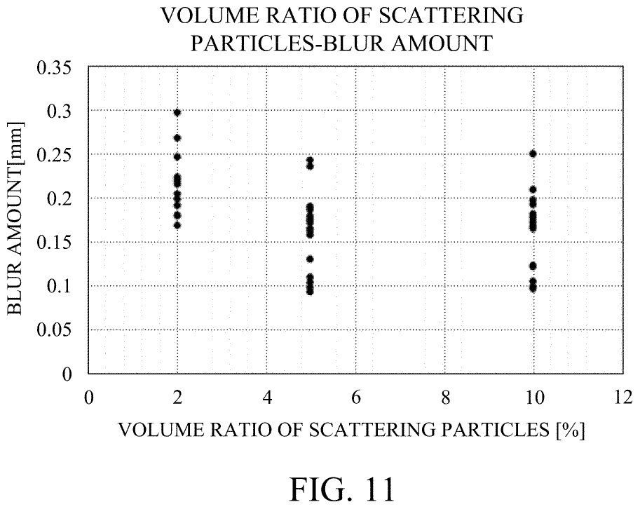

FIG. 9 illustrates a relationship between the refractive index of light-scattering particles and the blur amount. In FIG. 9, the ordinate axis represents the blur amount (mm), and the abscissa axis represents the refractive index of the light-scattering particles. FIG. 10 illustrates a relationship between the average particle radius of the light-scattering particles and the blur amount. In FIG. 10, the ordinate axis represents the blur amount (mm), and the abscissa axis represents the average particle radius (nm) of the light-scattering particles. FIG. 11 illustrates a relationship between the volume ratio of the light-scattering particles and the blur amount. In FIG. 11, the ordinate axis represents the blur amount (mm), and the abscissa axis represents the volume ratio (%) of the light-scattering particles. FIGS. 9 to 11 illustrate only conditions within a proper range of B/Y in order to obtain the white light illustrated in FIG. 5. In order to reduce the blur amount within a proper B/Y range for obtaining the white light, the average particle radius of the light-scattering particles may be 75 nm or more and 200 nm or less, as illustrated in FIG. 10. From FIG. 11, the volume ratio of the light-scattering particles may be 5% or higher.

Thus, by properly selecting the refractive index, average particle radius, and volume ratio of the light-scattering particles contained in the phosphor, the light utilization efficiency of the fluorescent light emitted from the phosphor and the thermal conductivity of the phosphor can be more stably improved than the prior art that uses voids for the light-scattering particles. As a result, the light source apparatus can be stably made highly efficient and made small. This embodiment uses TiO₂ for the light-scattering particles, but the present invention is not limited to this embodiment. The light-scattering particles may have a refractive index higher than that of the light-transmitting member and a large difference in refractive index from the light-transmitting member.

### Third Embodiment

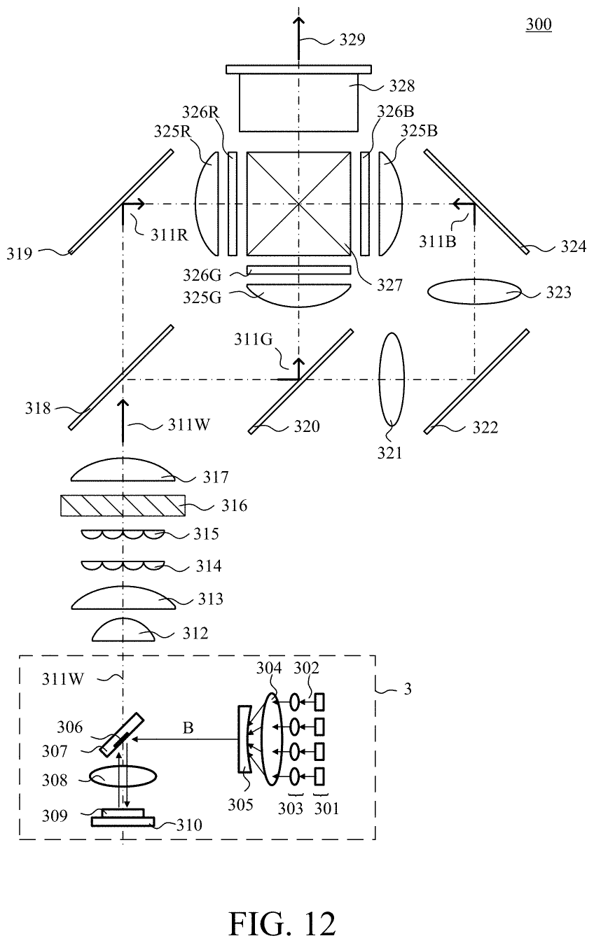

Referring now to FIG. 12, a description will be given of an image projection apparatus (projector) 300 according to a third embodiment of the present invention. FIG. 12 is a configuration diagram of the image projection apparatus 300. The image projection apparatus 300 includes a light source apparatus 3. In the following description, W, R, G, and B denote white, red, green, and blue, respectively.

Reference numeral 301 denotes each of a plurality of second blue light sources, reference numeral 302 denotes second blue light, reference numeral 303 denotes each of a plurality of second collimator lenses, reference numeral 304 denotes a sixth lens, and reference numeral 305 denotes a seventh lens. Reference numeral 306 denotes a second light reflector, reference numeral 307 denotes a flat plate, reference numeral 308 denotes an eighth lens, reference numeral 309 denotes a second phosphor (wavelength conversion element), reference numeral 310 denotes a second phosphor support member, and reference numeral 311W denotes illumination light. Reference numeral 312 denotes a ninth lens, reference numeral 313 denotes a tenth lens, reference numeral 314 denotes a first fly-eye lens, reference numeral 315 denotes a second fly-eye lens, reference numeral 316 denotes a polarization conversion element, and reference numeral 317 denotes a superimposing lens. Reference numeral 318 denotes a first dichroic mirror, reference numeral 319 denotes a second mirror, reference numeral 320 denotes a second dichroic mirror, reference numeral 321 denotes a first relay lens, reference numeral 322 denotes a third mirror, reference numeral 323 denotes a second relay lens, and reference numeral 324 denotes a fourth mirror. Reference numerals 325R, 325B, and 325G denote field lenses, reference numerals 326R, 326B, and 326G are light modulation elements (LCDs), reference numeral 327 denotes a cross dichroic prism, reference numeral 328 denotes a projection lens (projection optical system), and reference numeral 329 denotes second projection light.

The second blue light source 301 is a semiconductor laser that emits the second blue light 302, and serves as an excitation light source that excites the second phosphor 309 as a wavelength conversion element. The second phosphor 309 has the same structure as that of the phosphor 1 illustrated in FIG. 1. The image projection apparatus 300 according to this embodiment includes four second blue light sources 301, but the number of the second blue light sources 301 is not limited to four. The blue light emitted by the second blue light source 301 has a peak wavelength of 455 nm.

The blue light 302 as the divergent light emitted from the second blue light source 301 is converted into parallel light by the second collimator lens 303 and enters the sixth lens 304 as the beam shaping lens. The sixth lens 304 adjusts the sectional shape of the second blue light 302 from the second collimator lens 303. The second blue light 302 as the excitation light emitted from the sixth lens 304 is reflected by the second dichroic film 306 provided on part of the second flat plate 307, and is irradiated onto the second phosphor 309 via the eighth lens 308. The second flat plate 307 is made of a glass material. The second dichroic film 306 has a characteristic of transmitting the blue light and reflecting the yellow light.

The second phosphor 309 is a sintered material or sintered body made of YAG:Ce, Al₂O₃, and TiO₂, similarly to the first phosphor 209 in the second embodiment. The second phosphor 309 is supported by the second phosphor support member 310. The second phosphor support member 310 is typically made of a metal plate such as copper. However, it is not limited to the metal plate as long as it has the same function as the metal plate. In order to efficiently radiate heat from the second phosphor 309, the second phosphor 309 and the second phosphor support member 310 may be rotated by using a motor or the like. The second phosphor 309 wavelength-converts part of the second blue light 302 into the yellow fluorescent light, which is combined with the blue excitation light that has not been wavelength-converted to form the illumination light 311.

The ninth lens 312 and the tenth lens 313 convert the white illumination light (illumination light 311) as the divergent light emitted from the second phosphor 309 into substantially parallel light. The illumination light 311 enters the first fly-eye lens 314. The first fly-eye lens 314 has a plurality of small lenses for dividing the illumination light 311 into a plurality of light beams. The plurality of small lenses are arranged in a matrix shape in a plane orthogonal to the optical axis. The second fly-eye lens 315 has a plurality of small lenses arranged in a matrix shape in a plane orthogonal to the optical axis and corresponding to the plurality of small lenses of the first fly-eye lens 314. The second fly-eye lens 315, together with the superimposing lens 317, forms an image of each small lens of the first fly-eye lens 314 near the light modulation elements 326R, 326G, and 326B. The illumination light 311 as the plurality of light beams emitted from the second fly-eye lens 315 enters the polarization conversion element 316.

The polarization conversion element 316 converts the illumination light 311 as nonpolarized light from the second fly-eye lens 315 into linearly polarized light. More specifically, the polarization conversion element 316 transmits the linearly polarized light component of the illumination light 311 in a direction (x direction) orthogonal to the optical axis and parallel to the paper plane, and converts a linearly polarized light component in a direction (y direction) orthogonal to the optical axis and orthogonal to the paper plane into the linearly polarized light component in the x direction using a retardation plate. The illumination light 311 as the linearly polarized light emitted from the polarization conversion element 316 enters the superimposing lens 317.

The superimposing lens 317 condenses a plurality of light beams from the polarization conversion element 316 and superimposes them on the light modulation elements 326R, 326G, and 326B. The first fly-eye lens 314, the second fly-eye lens 315, and the superimposing lens 317 have a function of making uniform the light intensity distribution of the illumination light 311W on each light modulation element. The illumination light 311W emitted from the superimposing lens 317 enters the first dichroic mirror 318. The first dichroic mirror 318 has a characteristic of transmitting red light and reflecting green and blue light. The red light 311R that has transmitted through the first dichroic mirror 318 in the illumination light 311W is reflected by the second mirror 319, passes through the field lens 325R, and enters the light modulation element 326R.

The green and blue light reflected by the first dichroic mirror 318 is guided to the second dichroic mirror 320. The second dichroic mirror 320 has a characteristic of reflecting the green light and transmitting the blue light. The green light 311G reflected by the second dichroic mirror 320 passes through the field lens 325G and enters the light modulation element 326G.

The blue light 311B that has transmitted through the second dichroic mirror 320 enters the field lens 325B via the first relay lens 321, the second mirror 322, the second relay lens 323, and the third mirror 324. Then, the blue light 311B passes through the field lens 325B and enters the light modulation element 326B.

Each of the light modulation elements 326R, 326G, and 326B includes a liquid crystal element, a digital micromirror device, and the like. The light modulation elements 326R, 326G, and 326B modulate the incident red light 311R, green light 311G, and blue light 311B based on the video signal (image information) input to the image projection apparatus 300 to form image light, respectively. The red light 311R, green light 311G, and blue light 311B modulated by the light modulation elements 326R, 326G, and 326B are combined by the cross dichroic prism 327 and enter the projection lens 328. The cross dichroic prism 327 has a characteristic of transmitting the green light and reflecting the red light and blue light. The projection lens 328 magnifies and projects the combined image light (projection light) 329 onto a projection surface such as a screen (not shown). Thereby, a full-color projection image is displayed.

Thus, properly selecting the refractive index, volume ratio, and average particle radius of the light-scattering particles contained in the phosphor can more stably improve the light utilization efficiency of the fluorescent light emitted from the phosphor and the thermal conductivity of the phosphor than the prior art that uses voids for the light-scattering particles. As a result, the yield of the image projection apparatus can be improved.

Each embodiment can provide a wavelength conversion element, a light source apparatus, and an image projection apparatus, each of which can stably improve the heat radiation and light utilization efficiency.

While the present invention has been described with reference to exemplary embodiments, it is to be understood that the invention is not limited to the disclosed exemplary embodiments. The scope of the following claims is to be accorded the broadest interpretation so as to encompass all such modifications and equivalent structures and functions.

This application claims the benefit of Japanese Patent Application No. 2020-146627, filed on Sep. 1, 2020, which is hereby incorporated by reference herein in its entirety.

What is claimed is:

1. A wavelength conversion element made of a sintered body, the wavelength conversion element comprising:
a fluorescent member;
a light-transmitting member having a thermal conductivity higher than that of the fluorescent member; and
a light-scattering member having a refractive index higher than that of the light-transmitting member, and an average particle radius of 75 nm or more and 200 nm or less.

2. The wavelength conversion element according to claim 1, wherein the fluorescent member is made of Y₃Al₅O₁₂:Ce.

3. The wavelength conversion element according to claim 1, wherein the light-transmitting member is made of Al₂O₃.

4. The wavelength conversion element according to claim 1, wherein the refractive index of the light-scattering member is 2.2 or higher.

5. The wavelength conversion element according to claim 1, wherein a ratio of a volume of the light-scattering member to a volume of the wavelength conversion element is 2% or higher.

6. The wavelength conversion element according to claim 1, wherein the light-scattering member is made of TiO₂.

7. The wavelength conversion element according to claim 6, wherein the light-scattering member has a rutile type crystal structure.

8. A light source apparatus comprising:
a wavelength conversion element made of a sintered body; and
a light source configured to excite the wavelength conversion element, and
wherein the wavelength conversion element includes:
a fluorescent member;
a light-transmitting member having a thermal conductivity higher than that of the fluorescent member; and
a light-scattering member having a refractive index higher than that of the light-transmitting member, and an average particle radius of 75 nm or more and 200 nm or less.

9. The light source apparatus according to claim 8, wherein of light emitted from the light source apparatus, a ratio of a light amount in a wavelength range of the light source to a light amount in a wavelength range of the wavelength conversion element is 0.28 or higher and 0.56 or lower.

10. An image projection apparatus comprising:
a light source apparatus; and
a light modulation element configured to modulate light from the light source apparatus to form image light based on image information,
wherein the light source apparatus includes:
a wavelength conversion element made of a sintered body; and
a light source configured to excite the wavelength conversion element, and
wherein the wavelength conversion element includes:
a fluorescent member;
a light-transmitting member having a thermal conductivity higher than that of the fluorescent member; and
a light-scattering member having a refractive index higher than that of the light-transmitting member, and an average particle radius of 75 nm or more and 200 nm or less.
